(19) United States
(12) Patent Application Publication
(10) Pub. No.: US 2006/0114072 A1
(43) Pub. Date: Jun. 1, 2006

(54) Methods and apparatuses for changing capacitance

(76) Inventors: Seung-won Lee, Seongnam-si (KR); Hwi-taek Chung, Suwon-si (KR); Byeong-hoon Lee, Seoul (KR)

Correspondence Address: HARNESS, DICKEY & PIERCE, P.L.C., P.O. BOX 8910, RESTON, VA, 20195, US

(21) Appl. No.: 11/289,286

(22) Filed: Nov. 30, 2005

(30) Foreign Application Priority Data
Nov. 30, 2004 (KR) 10-2004-0099057

(51) Int. Cl. H03K 3/03

(52) U.S. Cl. 331/57

(57) ABSTRACT

Methods and apparatuses for changing capacitance are provided. The apparatus may adjust a current supplied to a load capacitor according to the frequency of an input clock signal. When operating at a lower frequency, a capacitance may be increased such that noise immunity may be increased. When operating at a higher frequency, a capacitance may be decreased such that current consumption may be reduced.

### PRIORITY STATEMENT

This non-provisional U.S. application claims priority under 35 U.S.C. §119 to Korean Patent Application No. 10-2004-0099057, filed on Nov. 30, 2004, in the Korean Intellectual Property Office, the entire contents of which are incorporated herein by reference.

### BACKGROUND

1. Field of the Invention

Example embodiments of the present invention relate to apparatuses and methods for changing capacitance.

2. Description of the Conventional Art

FIG. 1 is a block diagram of a conventional phase locked loop (PLL) 10. The PLL 10 may include a phase detector 11, a charge pump 12, a voltage controlled oscillator (VCO) 13, and a frequency divider 14.

The phase detector 11 may compare the phase of an external input clock signal ext. CLK with the phase of an output clock signal fed back by the frequency divider 14. The output is the result of the comparison. The charge pump 12 may alter a control voltage in response to a signal output from the phase detector 11. The phase detector 11 may output the control voltage. The VCO 13 may control the current charged/discharged from a load capacitor inside the VCO 13 in response to the control voltage output from the charge pump 12. The VCO 13 may generate an oscillation voltage having a frequency corresponding to the control voltage. The frequency divider 14 may divide the oscillation voltage signal output from the VCO 13 and feed back the divided oscillation voltage signal to the phase detector 11.

FIG. 2 is an example circuit diagram of the VCO 13. The VCO 13 may include a plurality of transistors (e.g., PMOS transistors) 21, a plurality of transistors (e.g., NMOS transistors) 22, an inverter 23, and a load capacitor 24. The transistors 21 and the transistors 22 may allow current corresponding to a control voltage Vctrl(p) to flow through the inverter 23 in response to the control voltage Vctrl(p) and/or a control voltage Vctrl(n). The inverter 23 may invert and output an input signal from the load capacitor 24, charge/discharge using the transistor 21 and the transistor 22, and generating an oscillating signal corresponding to the control voltage Vctrl(n). Although not shown in FIG. 2, the VCO 13 may include a resistor and/or an inductor connected in parallel with the load capacitor 24, for example, at an output terminal of the inverter 23 to generate a resonance frequency.

The conventional PLL shown in FIG. 1 may include a VCO (e.g., FIG. 2) in which an output frequency may be determined by controlling current when generating an internal clock signal int. CLK is synchronized with the external input clock signal ext. CLK. The VCO may be designed to be phase locked using a larger current when an external input clock ext. CLK signal has a higher frequency and using a smaller current when the external input ext. CLK clock signal has a lower frequency. When the external input clock ext. CLK signal has a lower frequency, the conventional PLL may be driven with a smaller current and may be more susceptible to, for example, noise interference. When the external input clock ext. CLK signal has a higher frequency, the conventional PLL may have a higher current consumption and operable frequency range may be narrower.

### SUMMARY OF THE INVENTION

Example embodiments of the present invention provides a voltage controlled oscillator (VCO) which may increase the capacitance of an output node, for example, such that the current used may not be reduced at lower frequencies and/or may decrease the capacitance of the output node such that current consumption may be reduced at higher frequencies and an actual operable frequency band of the VCO may be widened.

An example embodiment of the present invention provides an apparatus, which may include a phase detector, a charge pump, a voltage controlled oscillator, a frequency divider and/or a frequency range detector. The phase detector may compare the phase of an input clock signal with the phase of a fed-back output clock signal. The phase detector may output a result of comparison. The charge pump may output a control voltage based on the output of the phase detector. The voltage controlled oscillator may generate an oscillation signal having a frequency corresponding to the control voltage output from the charge pump. The voltage controlled oscillator may output the oscillation signal as a clock signal. The frequency divider may divide the clock signal output from the voltage controlled oscillator and may feed back the divided clock signal to the phase detector. The frequency range detector may divide a frequency band of the input clock signal into a plurality of frequency ranges. The frequency range detector may output a frequency range detection signal corresponding to the initial frequency range of the input signal. The voltage controlled oscillator may include a plurality of load capacitors. The load capacitors may provide a variable capacitance corresponding to the frequency range detection signal.

Another example embodiment of the present invention provides an oscillator. The oscillator may include a plurality of amplifiers. The plurality of amplifiers may generate an oscillation signal having a resonance frequency according to a control voltage and variations in inductance and capacitance. The plurality of amplifiers may output the oscillation signal. The plurality of load capacitors may have variable capacitances corresponding to an initial frequency range of an input signal.

Another example embodiment of the present invention provides a decoder. The decoder may include a plurality of logic circuits. Each of the plurality of logic circuits may each have at least two inputs and one output. Each may activate a respective frequency detection signal in response to receiving at least two frequency signals and/or at least two frequency signals and at least one frequency detection signal.

Another example embodiment of the present invention provides a detector. The detector may include a plurality of delay units each of which may delay a clock signal. Each of a plurality of logic units may received the clock signal and a delayed clock signal, and may output a respective output signal based on the received clock signal and delayed clock signal. Each of the delayed clock signals may be output from a respective one of the plurality of delay units. A decoder may receive each output signal and output a frequency selection signal indicative of a selected frequency range based on the received output signals.

In a method according to an example embodiment of the present invention, a phase of an input clock signal may be compared with the phase of a fed-back output clock signal. The result of the comparison may be output. A control voltage may be output based on the comparison result. An oscillation signal having a frequency corresponding to the output control voltage may be generated and output as a clock signal. The output clock signal may be divided to generate the fed-back output clock signal. A frequency band of the input clock signal may be divided into a plurality of frequency ranges. The frequency range detection signal corresponding to the initial frequency range of the input signal may be output. The oscillation signal may be generated using a variable capacitance corresponding to the frequency range detection signal.

In example embodiments of the present invention, each of the load capacitors may further include a plurality of capacitors having different capacitances and connected in parallel. The load capacitors may also include a plurality of switches, each of which may be connected between one of the plurality of capacitors and a ground voltage. The plurality of switches may be turned on or off according to the initial frequency range of the input signal.

In example embodiments of the present invention, the capacitance of each of the load capacitors may increase as the frequency of the input clock signal enters a lower frequency range.

In example embodiments of the present invention, the frequency band of the input signal may be divided into N frequency ranges, and the plurality of switches may include N switches. Each of the N switches may correspond to a respective one of the frequency ranges or log2(N) switches may correspond to combinations of the N frequency ranges.

In example embodiments of the present invention, the capacitance of the load capacitor may be increased, for example, by closing one of the switches connected to one of the capacitor with a lower capacitance as the frequency of the input clock signal enters a lower frequency band.

In example embodiments of the present invention, the switch corresponding to frequency range may not be toggled, for example, when the frequency of the input signal enters a frequency range adjacent to the initial frequency range.

In example embodiments of the present invention, the oscillator may further include a plurality of inductors. The plurality of conductors may be connected in parallel with a respective load capacitor and may generate an inductance. A plurality of resistors may be connected in parallel with one of the respective load capacitors and may generate a resistance.

In example embodiments of the present invention, the voltage controlled oscillator may include a plurality of amplifiers. The plurality of amplifiers may generate the oscillation signal having a resonance frequency according to an input control voltage and/or changes in inductance and capacitance, and outputting the oscillation signal.

### BRIEF DESCRIPTION OF THE DRAWINGS

The above and other aspects of example embodiments of the present invention will become more apparent by describing in detail example embodiments thereof with reference to the attached drawings in which:

FIG. 1 is a block diagram of a conventional phase locked loop (PLL);

FIG. 2 is an example circuit diagram of a conventional voltage controlled oscillator (VCO);

FIG. 3 is a block diagram of a phase locked loop (PLL) according to an example embodiment of the present invention;

FIG. 4 is a circuit diagram of a voltage controlled oscillator (VCO) according to an example embodiment of the present invention;

FIG. 5 illustrates a method for generating frequency detection signals according to an example embodiment of the present invention;

FIG. 6 illustrates a method for generating frequency range detection signals according to an example embodiment of the present invention; and

FIG. 7 is a block diagram of a decoder according to an example embodiment of the present invention.

### DETAILED DESCRIPTION OF EXAMPLE EMBODIMENTS OF THE PRESENT INVENTION

Various example embodiments of the present invention will now be described more fully with reference to the accompanying drawings in which some example embodiments of the invention are shown. In the drawings, the thicknesses of layers and regions are exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

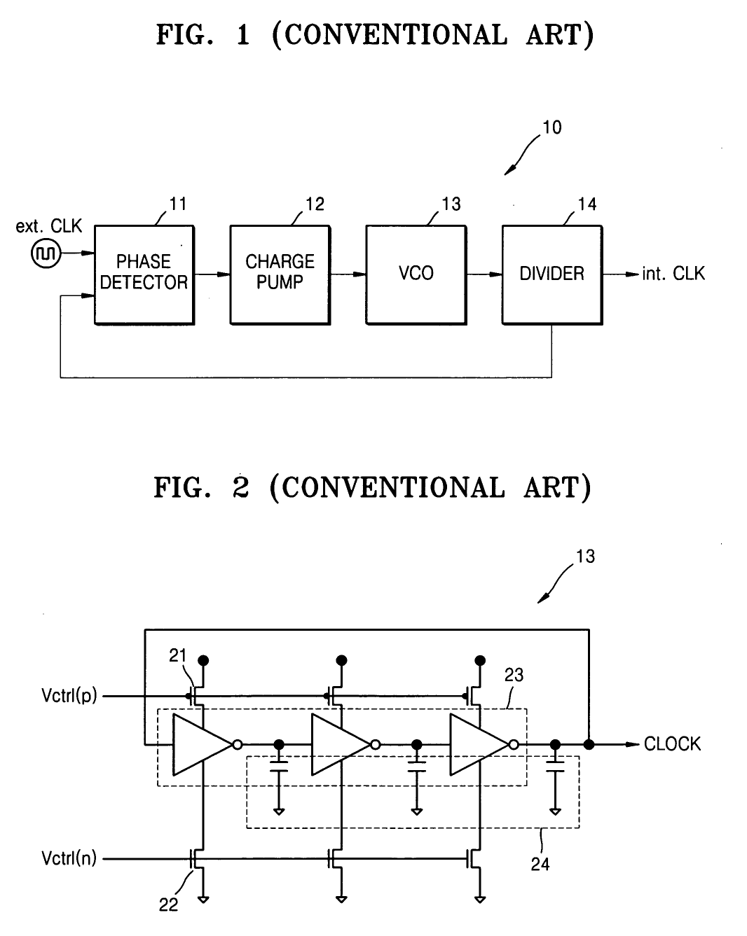

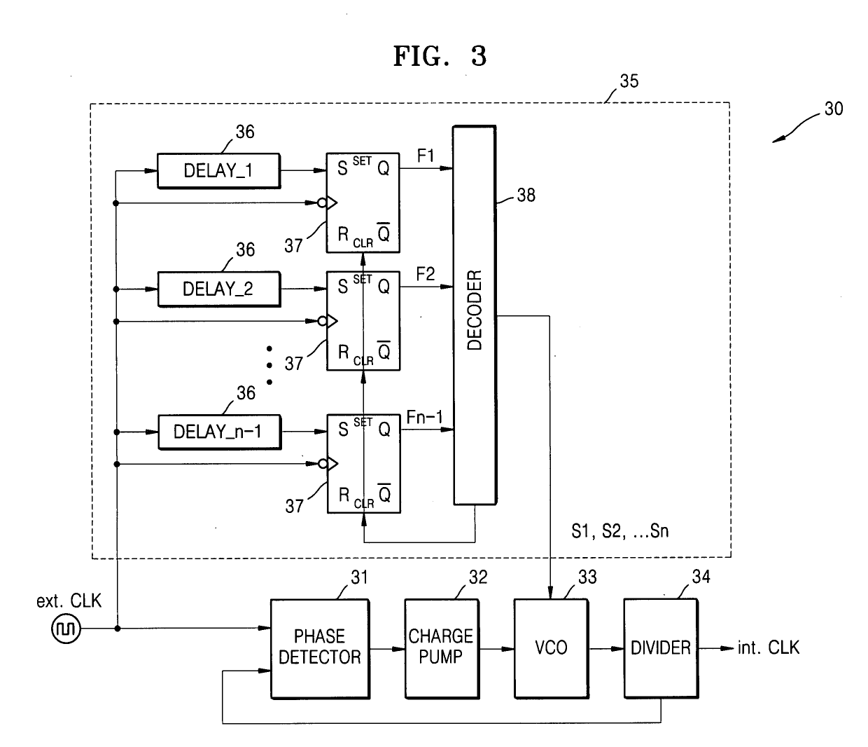

FIG. 3 is a block diagram of a phase locked loop (PLL) 30 according to an example embodiment of the present invention. Referring to FIG. 3, the PLL 30 may include a phase detector 31, a charge pump 32, a voltage control oscillator (VCO) 33, a frequency divider 34 and/or a frequency range detector 35. The phase detector 31, the charge pump 32 and/or the frequency divider 34 may be the same, or substantially the same, similar, or substantially similar, to the phase detector 11, the charge pump 12 and/or the frequency divider 14 of FIG. 1.

The frequency range detector 35 may include a plurality of delay units 36 having different delays, a plurality of flip-flops 37 which may output signals F1, F2, . . . , and Fn−1, respectively. The signals F1, F2, . . . , and Fn−1 may be generated in response to respective differences between the signals outputted from the plurality of delay units 36 and an input signal. The frequency range detector 35 may further include a decoder 38, which may detect the frequency range of an input clock signal by decoding signals output from the plurality of flip-flops 37. The frequency range detector 35 may output corresponding frequency detection signals S1, S2, . . . , and Sn.

The frequency range detector 35 may divide the frequency range of the input clock signal by n and detect to which of n regions a frequency belongs. The frequency range detector 35 may output corresponding frequency detection signals S1, S2, . . . , and Sn to the VCO 33.

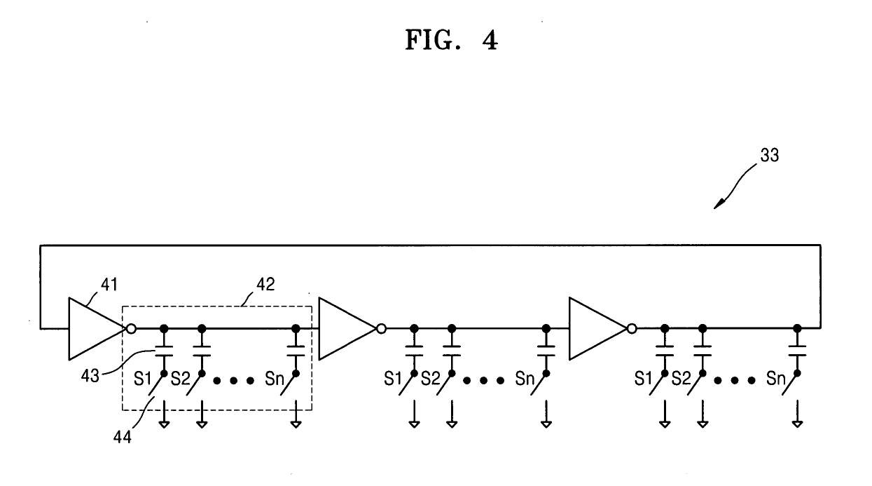

FIG. 4 is a circuit diagram of a voltage controlled oscillator (VCO) 33 according to an example embodiment of the present invention. The VCO 33 may include a plurality of amplifiers (e.g., transconductance amplifiers, although any suitable amplifier may be used) 41, for example, connected in series, and a plurality of load capacitors 42 connected between the amplifiers 41. Although not shown in FIG. 4, inductors and/or resistors for generating a resonance frequency may be connected to the load capacitors 42.

Each of the load capacitors 42 may include a plurality of capacitors 43. Each of the capacitors 43 may have different capacitances and may be connected, for example, in parallel. One of a plurality of switches 44 may be connected between each of the capacitors 43 and a ground voltage, respectively. The switches 44 may be opened and closed in response to the frequency detection signals S1, S2, . . . , and Sn output from the frequency range detector 35.

Each of the amplifiers 41 may include transistors (e.g., NMOS, PMOS, CMOS, any MOS-type, or any suitable transistors) allowing a current corresponding to a control voltage 40 to flow through the amplifiers 41. Each amplifier 41 may also include inverters, which may invert input clock signals between the transistors.

For example, a VCO of a PLL may include an odd number of inverters and an output and input of the VCO may vary at opposite phases. The VCO of the PLL may have a capacitor connected to an output node and current from input to output may be delayed. The frequency of a clock signal output from the VCO may be determined by current used to charge/discharge a capacitor. For example, in a smart card, the frequency band of an external clock signal may be between about 1 and about 5 MHz. The frequency band of the internal clock signal may be between about 8 and about 40 MHz. This may be obtained by multiplying the external frequency range by, for example, 8. A frequency band of the VCO may be between about 8 and about 40 MHz.

A current flowing through the VCO when operating at a frequency of 8 MHz may be, for example, ⅕ the current as compared to operation at 40 MHz. Since a reduction in current results in a reduction in noise immunity, noise immunity in a low frequency operation may be less than in higher frequency operation.

Noise immunity in a lower frequency operation may be increased by increasing an operating current. Since the current corresponding to higher frequency operation may be higher (e.g., substantially higher) than the current corresponding to lower frequency operation and the input to the VCO may be limited, the frequency (e.g., maximum frequency) may be decreased.

For example, an internal clock signal having the same, or substantially the same, frequency may be generated while current consumption is increased and the size of the actual frequency range may be decreased.

The PLL 30 according to example embodiments of the present invention may alter the load capacitance inside the VCO 33, for example, by detecting the frequency of an input clock signal. For example, when the frequency of the input clock signal is detected by the frequency range detector 35 and/or a frequency detection signal corresponding to a frequency range is detected, the switches 44 may open/close in response to the frequency detection signals S1, S2, . . . , and Sn. The capacitance of the load capacitors 42 may be altered.

After an operating frequency range for the PLL 30 is determined by detecting the frequency of the input clock signal, if the clock signal has a lower frequency, the capacitances of the load capacitors 42 may be increased. This may increase the operating current, for example, when the VCO 33 is configured to improve noise immunity. When the clock signal has a higher frequency, the capacitances of the load capacitors 42 may be decreased and an operating current of the VCO 33 may be decreased, for example, such that current consumption in a higher frequency range may be reduced and/or the size of the operating frequency band may be increased.

The input clock signal may be divided into a number of frequency ranges. Each of the frequency ranges may correspond to one of the switches 44, respectively, connected to the load capacitors 42 such that the frequency range may be selected.

When the frequency range detector 35 divides the frequency band of the input clock signal by n and outputs the n frequency detection signals S1, S2, . . . , and Sn corresponding to the frequency ranges, the n frequency detection signals S1, S2, . . . , and Sn may be input to each of the n switches 44. The n switches may be connected in series to n capacitors 43, which may have the same, or substantially the same, or different capacitances.

A frequency detection signal corresponding to a higher frequency range may be input to one of the switches 44 connected to one of the capacitors 43 having a smaller capacitance. A frequency detection signal corresponding to a lower frequency range may be input to one of the switches 44 connected to one of the capacitors 43 having a large capacitance. As the frequency of the input clock signal increases, one of the switches 44 connected to one of the smaller capacitors 43 may be closed and the VCO 33 may operate with a lower current such that the operating frequency band may be increased. As the frequency of the input clock signal decreases, one of the switches 44 connected to one of the larger capacitors 43 may be closed and the VCO 33 may operate with a higher current. This may increase noise immunity in lower frequency operation.

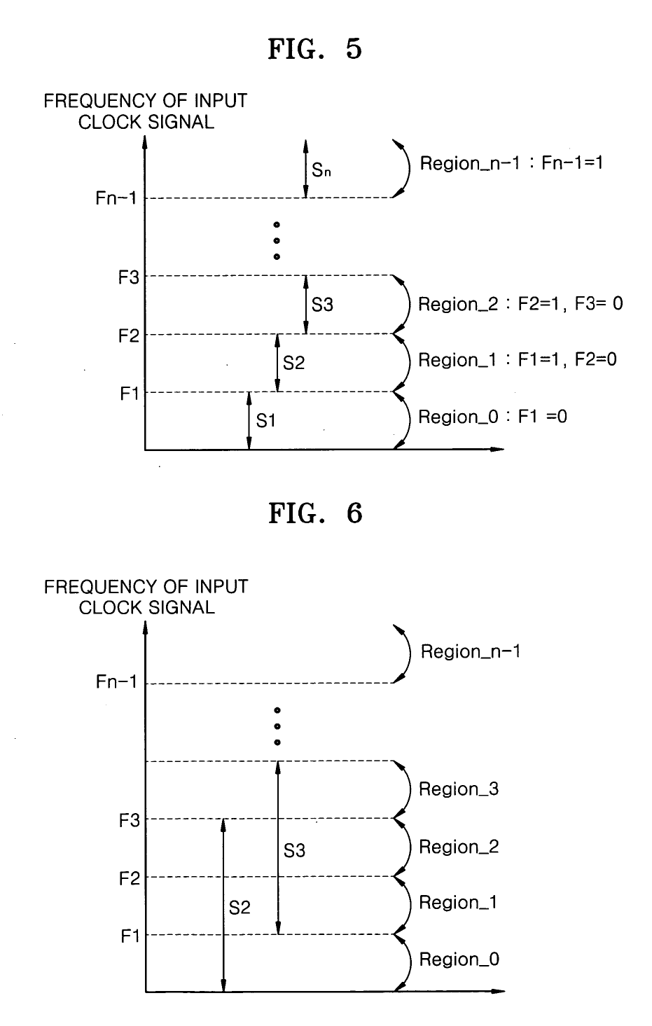

FIG. 5 illustrates a method for generating frequency detection signals S1, S2, . . . , and Sn according to an example embodiment of the present invention. When the frequency band of the input clock signal is divided into n frequency ranges, such as, a region of frequencies less than, or equal to a first frequency F1 (Region_0), a region of frequencies between the first frequency F1 and a second frequency F2 (Region_1), a region of frequencies between the second frequency F2 and a third frequency F3 (Region_2), . . . , a region of frequencies between a (n−2)th frequency Fn−2 and a (n−1)th frequency Fn−1 (Region_n−2), and a region of frequencies greater than, or equal to, the (n−1)th frequency Fn−1 (Region_n−1), Region_0 may correspond to the capacitor 43 having a larger (e.g., the largest) capacitance and Region_n−1 may correspond to the capacitor 43 having a smaller (e.g., the smallest) capacitance.

When the frequency of the input clock signal corresponds to Region_0, the flip-flops 37 of the frequency range detector 35 may output F1=F2= . . . Fn−1=0. When the frequency of the input clock signal corresponds to Region_{—}1, the flip-flops 37 may output F1=1, F2=F3= . . . Fn−1=0. When the frequency of the input clock signal corresponds to Region_n−1, the flip-flops 37 may output F1=F2= . . . Fn−1=1.

The decoder 38 may activate the frequency detection signal S1. This may indicate that the frequency of the input clock signal corresponds to Region_0, for example, when the flip-flops 37 output F1=F2= . . . Fn−1=0. In another example, the frequency detection signal S2 may be activated. This may indicate that the frequency of the input clock signal corresponds to Region_1 when the flip-flops 37 output F1=1, F2=F3= . . . Fn−1=0. In yet another example, frequency detection signal S1 may be activated. This may indicate that the frequency of the input clock signal corresponds to Region_n−1 when the flip-flops 37 output F1=F2= . . . Fn−1=1.

When the capacitance of the VCO 33 is changed (e.g., rapidly) according to a change of a frequency range of the input clock signal, unstable switching may occur due to, for example, jitter of the input clock signal. When the frequency of the input clock signal changes to a frequency corresponding to an adjacent frequency range, the VCO 33 may be set such that the capacitance of the load capacitor 42 may not change.

FIG. 6 illustrates another method for generating frequency detection signals S1, S2, . . . , and Sn according to an example embodiment of the present invention. The switch 44 corresponding to Region_i−1 among n frequency ranges of the input clock signal may not be toggled when a frequency range in which the frequency of the input clock signal changes to Region_i−2 or Region_i adjacent to the i-th frequency range. The switch 44 corresponding to Region_i may be toggled when the frequency range in which the frequency of the input clock signal changes to a non-adjacent frequency range, for example, Region_i−3 or below or Region_i+1 or above.

The switches 44 may toggle when the frequency of the input clock signal changes from an initial frequency range to a frequency range separated by at least one other frequency range from the initial frequency range, and the switches 44 may not toggle when the frequency of the input clock signal changes from an initial frequency range to an adjacent frequency range. The charged capacitor 43 may be changed when a larger change in the frequency of the input clock signal occurs. This may correct for jitter of the input clock signal.

For example, referring to FIG. 6, when the frequency of the input clock signal is initially between the first frequency F1 and the second frequency F2 (Region_1), the closed switch 44 may correspond to the frequency detection signal S2. When it is determined that the frequency of the input clock signal is between the second and third frequencies F2 and F3 (Region_2) during the operation of the PLL, the frequency range detector 35 may not activate the frequency detection signal S3 corresponding to Region_2, but may maintain the active frequency detection signal S2. In this example, the capacitance of the load capacitor 42 may remain constant, or substantially constant, until the frequency range detector 35 detects a frequency greater than, or equal to, F3, and outputs one of the frequency detection signals S4, S5, . . . , and Sn.

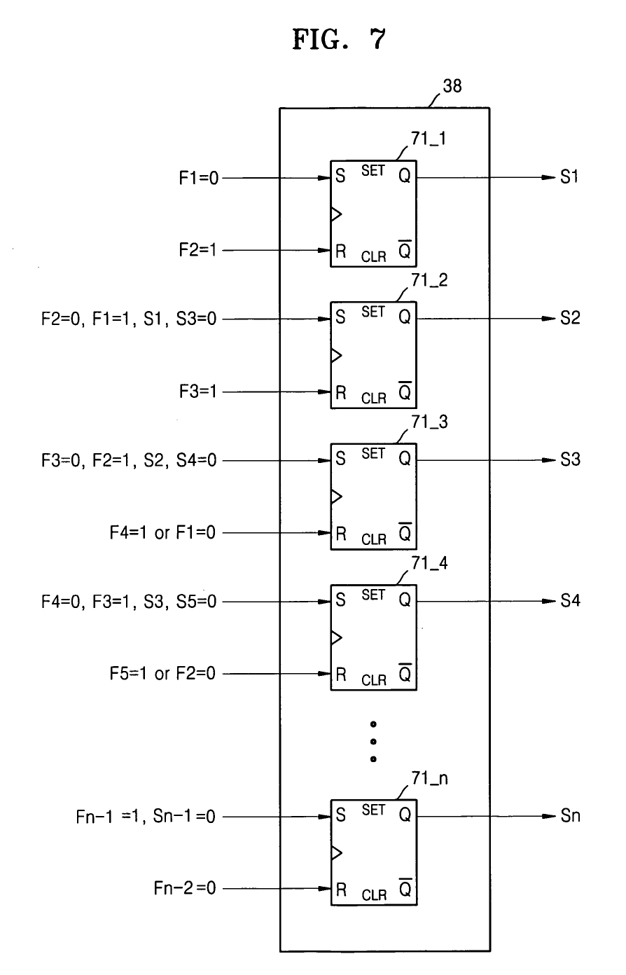

FIG. 7 is a block diagram of the decoder according to an example embodiment of the present invention. A decoder 38 of the frequency range detector 35 may include n flip-flops 71_1 through 71_n so that the frequency range to which the capacitances of the load capacitors 42 corresponds may not change, for example, when the frequency region in which the frequency of the input clock signal exists is adjacent to the frequency range to which the capacitance of the load capacitor 42 corresponds. The first flip-flop 71_1 may activate the frequency detection signal S1 if F1=0 is received and may reset the frequency detection signal S1 when F2=1 is received.

The second flip-flop 71_2 may activate the frequency detection signal S2 if F2=0 and F1=1 are received and S1=S3=0. The second flip-flop 71_3 may reset the frequency detection signal S2 when F3=1 is received. The third flip-flop 71_3 may activate the frequency detection signal S3 if F3=0 and F2=1 are received and S2=S4=0. The third flip-flop 71_3 may reset the frequency detection signal S3 when F4=1 or F1=0 is received. The fourth flip-flop 71_4 may activate the frequency detection signal S4 if F4=0 and F3=1 are received and S3=S5=0. The fourth flip-flop 71_4 may reset the frequency detection signal S4 when F5=1 or F2=0 is received. The n-th flip-flop 71_n may activate the frequency detection signal Sn if Fn−1=1 is received and Sn−1=0. The n-th flip-flop 71_{—}n may reset the frequency detection signal S4 when Fn−2=0 is received.

When the decoder 38 is used, if the frequency of the input clock signal shifts to an adjacent frequency range, the activated frequency detection signal may not change and the capacitance of the load capacitors 42 may not change. The load capacitors 42 may operate more stably, for example, when clock jitter occurs.

As described above, in a voltage controlled oscillator (VCO) according to example embodiments of the present invention, the current used at lower frequencies may increase such that noise immunity may increase, and the current used at higher frequencies may be reduced such that the generated frequency range may increase.

Example embodiments of the present invention have been described with regard to specific voltage levels and/or logic signals. However, it will be understood that example embodiments of the present invention may utilize any suitable voltage levels and/or logic signals, for example, higher and lower voltage levels and/or logic high, ‘H’, ‘1’, low, ‘L’, or ‘0’ interchangeably.

While example embodiments of the present invention have been shown and described with reference to the drawings, it will be understood by those skilled in the art that various changes in form and details may be made therein without departing from the spirit and scope of the present invention as defined by the following claims.

What is claimed is:

1. An oscillator comprising:
a plurality of amplifiers generating an oscillation signal having a resonance frequency according to a control voltage and variations in inductance and capacitance, and outputting the oscillation signal; and
a plurality of load capacitors having variable capacitances corresponding to an initial frequency range of an input signal.

2. The oscillator of claim 1, wherein each of the load capacitors further includes,
a plurality of capacitors having different capacitances and connected in parallel, and
a plurality of switches each of which is connected between one of the plurality of capacitors and a ground voltage, and which is turned on or off according to the initial frequency range of the input signal.

3. The oscillator of claim 1, wherein the capacitance of each of the load capacitors increases as the frequency of the input clock signal enters a lower frequency range.

4. The oscillator of claim 2, wherein the frequency band of the input signal is divided into N frequency ranges, and the plurality of switches includes N switches each of which corresponds to a respective one of the frequency ranges or log₂(N) switches corresponding to combinations of the N frequency ranges.

5. The oscillator of claim 4, wherein the capacitance of the load capacitor is increased by closing one of the switches connected to one of the capacitor with a lower capacitance as the frequency of the input clock signal enters a lower frequency band.

6. The oscillator of claim 4, wherein the switch corresponding to frequency range is not toggled when the frequency of the input signal enters a frequency range adjacent to the initial frequency range.

7. The oscillator of claim 6, wherein the capacitance of the load capacitor is increased by closing one of the switches connected to one of the capacitor with a lower capacitance as the input clock signal enters a lower frequency band.

8. The oscillator of claim 1, further including,
a plurality of inductors each connected in parallel with a respective load capacitor and generating an inductance; and
a plurality of resistors connected in parallel with one of the respective load capacitors and generating a resistance.

9. An apparatus comprising:
a phase detector comparing the phase of an input clock signal with the phase of a fed-back output clock signal and outputting a result of comparison;
a charge pump outputting a control voltage based on the output of the phase detector;
a voltage controlled oscillator generating an oscillation signal having a frequency corresponding to the control voltage output from the charge pump and outputting the oscillation signal as a clock signal;
a frequency divider dividing the clock signal output from the voltage controlled oscillator and feeding back the divided clock signal to the phase detector; and
a frequency range detector dividing a frequency band of the input clock signal into a plurality of frequency ranges and outputting a frequency range detection signal corresponding to the initial frequency range of the input signal, wherein
the voltage controlled oscillator includes a plurality of load capacitors providing a variable capacitance corresponding to the frequency range detection signal.

10. The apparatus of claim 9, wherein the voltage controlled oscillator including a plurality of amplifiers generating the oscillation signal having a resonance frequency according to an input control voltage and changes in inductance and capacitance, and outputting the oscillation signal.

11. The apparatus of claim 10, wherein each of the load capacitors includes,
a plurality of capacitors having different capacitances connected in parallel to one another; and
a plurality of switches each of which is connected between a respective capacitor and a ground voltage, and turned on or off according to the frequency range of the inputted signal.

12. The apparatus of claim 10, wherein the capacitance of each of the load capacitors increases as the frequency of the detection signal output from the frequency range detector enters a lower frequency range.

13. The apparatus of claim 11, wherein the frequency band of the inputted signal is divided into N frequency ranges, and the plurality of switches includes N switches corresponding to each of the frequency ranges or log₂(N) switches corresponding to combinations of the N frequency ranges.

14. The apparatus of claim 13, wherein as a lower frequency band of the input clock signal is input to a switch connected to the capacitor having a higher capacitance, and as a higher frequency band of the input clock signal is input to a switch connected to the capacitor having a lower capacitance.

15. The apparatus of claim 13, wherein the switch corresponding to the initial frequency range of the input signal is not toggled when the frequency of the input signal enters an adjacent frequency range.

16. The apparatus of claim 15, wherein as a lower frequency band of the input clock signal is input to a switch connected to the capacitor having a higher capacitance, and as a higher frequency band of the input clock signal is input to a switch connected to the capacitor having a lower capacitance.

17. The apparatus of claim 9, wherein the voltage controlled oscillator further includes,
each of a plurality of inductors connected in parallel with a respective one of the load capacitors and generating an inductance, and
each of a plurality of resistors connected in parallel with a respective one of the load capacitors and generating a resistance.

18. A decoder comprising:
a plurality of logic circuits each having at least two inputs and one output; and each activating a respective frequency detection signal in response to receiving at least two frequency signals or at least two frequency signals and at least one frequency detection signal.

19. A detector comprising:
a plurality of delay units each delaying a clock signal;
a plurality of logic units, each receiving the clock signal and a delayed clock signal, and each outputting a respective output signal based on the received clock signal and delayed clock signal, each of the delayed clock signals being output from a respective one of the plurality of delay units; and
a decoder receiving each output signal and outputting a frequency selection signal indicative of a selected frequency range based on the received output signals.

20. A method comprising:
comparing a phase of an input clock signal with the phase of a fed-back output clock signal and outputting a result of comparison;
outputting a control voltage based on the output result;
generating an oscillation signal having a frequency corresponding to the output control voltage and outputting the oscillation signal as a clock signal;
dividing the output clock signal to generate the fed-back output clock signal; and
dividing a frequency band of the input clock signal into a plurality of frequency ranges and outputting a frequency range detection signal corresponding to the initial frequency range of the input signal, wherein
the oscillation signal is generated using a variable capacitance corresponding to the frequency range detection signal.

21. A detector including the decoder of claim 18.

22. An apparatus including the detector of claim 21.

23. An apparatus including the oscillator of claim 1.

24. An apparatus for performing the method of claim 20.
